(19) United States
(12) Patent Application Publication
(10) Pub. No.: US 2023/0337492 A1
(43) Pub. Date: Oct. 19, 2023

(54) ARRAY SUBSTRATE, DISPLAY PANEL AND DISPLAY DEVICE

(71) Applicant: Hefei Visionox Technology Co., Ltd., Hefei (CN)

(72) Inventors: Hongqing FENG, Hefei (CN); Hongrui LI, Hefei (CN); Xiangtao ZENG, Hefei (CN); Shaoyang QIN, Hefei (CN); Chengyu ZHAO, Hefei (CN); Shoukun WANG, Hefei (CN)

(73) Assignee: Hefei Visionox Technology Co., Ltd., Hefei (CN)

(21) Appl. No.: 18/337,601

(22) Filed: Jun. 20, 2023

Related U.S. Application Data
(63) Continuation of application No. PCT/CN2021/129190, filed on Nov. 8, 2021.

(30) Foreign Application Priority Data
Feb. 24, 2021 (CN) 202110206169.2

(51) Int. Cl. H10K 59/131; G09G 3/3225

(52) U.S. Cl. CPC H10K 59/131; G09G 3/3225; G09G 2300/0842; G09G 2300/0819

(57) ABSTRACT

An array substrate, a display panel and a display device. The array substrate includes: a plurality of first pixel circuits; a plurality of second pixel circuits; a plurality of first signal lines, wherein the plurality of first signal lines comprise a plurality of first type signal lines and a plurality of second type signal lines, and each of the second type signal lines comprises a first segment and a second segment separated by the hole region; a plurality of first connecting signal lines, wherein at least a part of the first connecting signal lines are located in the winding display region, the first connecting segment and the third connecting segment extend in a second direction, and the second connecting segment extends in the first direction.

### CROSS-REFERENCE TO RELATED APPLICATION

The present application is a continuation of International Application No. PCT/CN2021/129190 filed on Nov. 8, 2021, which claims priority to Chinese Patent Application No. 202110206169.2, filed on Feb. 24, 2021 and entitled “ARRAY SUBSTRATE, DISPLAY PANEL AND DISPLAY DEVICE”, both of which are hereby incorporated by reference in their entireties.

### TECHNICAL FIELD

The present application relates to a technical field of display, and particularly relates to an array substrate, a display panel and a display device.

### BACKGROUND

With rapid development of electronic devices, users have higher and higher requirements for screen ratio. Traditional electronic devices, such as mobile phones, tablet computers and the like, need to integrate devices such as front-facing cameras, handsets, infrared sensor components and the like. In the existing art, by notching or opening on the screen, external light can enter into the photosensitive component located below the screen through the notch or opening on the screen. Because that the signal lines around the notch or opening need to be connected in one-to-one correspondence, a large wiring space need to be set around the notch or opening, which affects the screen ratio of the display screen.

### SUMMARY

Embodiments of the present application provide an array substrate, a display panel and a display device, which can increase the screen ratio of the display region, and can improve the display effect.

In a first aspect, an embodiment of the present application provides an array substrate comprising a hole region and a display region, wherein the display region comprises a winding display region and a main display region, the winding display region is located between the hole region and the main display region, and the winding display region surrounds the hole region; wherein the array substrate comprises: a plurality of first pixel circuits distributed in an array in the winding display region; a plurality of second pixel circuits distributed in an array in the main display region; a plurality of first signal lines, wherein each of the first signal lines is electrically connected to the first pixel circuit and the second pixel circuit and extends along a first direction, the plurality of first signal lines comprise a plurality of first type signal lines and a plurality of second type signal lines, and each of the second type signal lines comprises a first segment and a second segment separated by the hole region; a plurality of first connecting signal lines, wherein at least a part of the first connecting signal lines are located in the winding display region, the first connecting signal line comprises a first connecting segment, a second connecting segment and a third connecting segment connected with each other, the first connecting segment is electrically connected to the first segment, the third connecting segment is electrically connected to the second segment, and the second connecting segment is connected between the first connecting segment and the third connecting segment, wherein the first connecting segment and the third connecting segment extend in a second direction, and the second connecting segment extends in the first direction; wherein an area of an orthographic projection of the first pixel circuit on a plane where the array substrate is located is smaller than an area of an orthographic projection of the second pixel circuit on the plane where the array substrate is located, and an orthographic projection of the first connecting signal line on the plane where the array substrate is located does not overlap with the orthographic projection of the first pixel circuit on the plane where the array substrate is located.

In a second aspect, an embodiment of the present application provides a display panel comprising the array substrate as described in any embodiment of the first aspect.

In a third aspect, an embodiment of the present application provides a display device comprising the display panel as described in the second aspect.

According to the array substrate, the display panel and the display device provided in the embodiments of the present application, on the one hand, since at least a part of the first connecting signal lines are disposed in the winding display region, the number of the first connecting signal lines disposed in the border of the hole region may be reduced, and the first connecting signal lines may even not be disposed in the border of the hole region. Therefore, the area of the border of the hole region can be reduced, and the screen ratio of the array substrate can be increased. On the other hand, by reducing the area of the first pixel circuit, the orthographic projection of the first connecting signal line on the plane where the array substrate is located does not overlap with the orthographic projection of the first pixel circuit on the plane where the array substrate is located. Therefore, the possibility of forming parasitic capacitance between the first connecting signal line and the first pixel circuit is reduced, the coupling effect between the first connecting signal line and the first pixel circuit can be weakened, and the display effect is improved.

### BRIEF DESCRIPTION OF THE DRAWINGS

Other features, purposes and advantages of the present application will be more apparent by reading the following detailed description of the non-restrictive embodiments with reference to the drawings. Here, the same or similar reference numbers indicate the same or similar features, and the drawings are not drawn to actual scale.

FIG. 1 illustrates a schematic top view of an array substrate provided by an embodiment of the present application;

FIG. 2 illustrates a schematic enlarged view of a Q1 region in FIG. 1;

FIG. 3 illustrates a schematic structural diagram of a first pixel circuit and a second pixel circuit provided by an embodiment of the present application;

FIG. 4 illustrates a schematic cross-sectional diagram of an A-A direction in FIG. 2;

FIG. 5 illustrates another schematic cross-sectional diagram of the A-A direction in FIG. 2;

FIG. 6 illustrates another schematic top view of an array substrate provided by an embodiment of the present application;

FIG. 7 illustrates a schematic enlarged view of a Q2 region in FIG. 6;

FIG. 8 illustrates another schematic enlarged view of the Q1 region in FIG. 1;

FIG. 9 illustrates a schematic cross-sectional diagram of a B-B direction in FIG. 8;

FIG. 10 illustrates a schematic structural diagram of a display panel provided by an embodiment of the present application.

### DETAILED DESCRIPTION

Features and exemplary embodiments of various aspects of the present application are described in detail below. In order to clarify the purposes, technical solutions and advantages of the present application, the present application will be further described in detail below in combination with the accompanying drawings and specific embodiments. It should be understood that the specific embodiments described herein are intended to interpret the present application and not to limit the present application. For those skilled in the art, the present application may be practiced without some of these specific details. The following description of the embodiments is merely to provide a better understanding of the present application by illustrating examples of the present application.

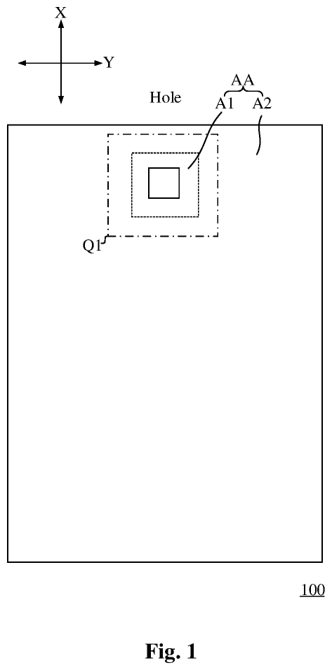

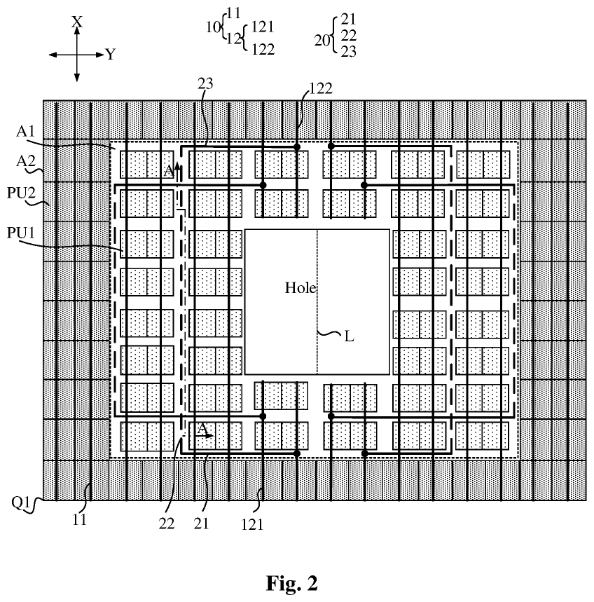

FIG. 1 illustrates a schematic top view of an array substrate provided by an embodiment of the present application. FIG. 2 illustrates a schematic enlarged view of a Q1 region in FIG. 1. As shown in FIGS. 1 and 2, the embodiment of the present application provides an array substrate 100 including a hole region Hole and a display region AA surrounding the hole region Hole. The display region AA includes a winding display region A1 and a main display region A2, wherein the winding display region A1 is located between the hole region Hole and the main display region A2, and the winding display region A1 surrounds the hole region Hole.

For example, the hole region Hole can also be called as an opening region, a notch region, a blind hole region, a via region and the like, which is not limited in the present application. The hole region Hole can be configured to place photosensitive components. The photosensitive component may be an image acquisition device for collecting external image information. For example, the photosensitive component is a camera. The photosensitive component may not be limited to the image acquisition device, for example in some embodiments, the photosensitive component may also be an optical sensor, such as an infrared sensor, a proximity sensor, an infrared lense, a floodlight sensing element, an ambient light sensor, and a lattice projector.

The hole region Hole may be a rectangular region, a circular region, an oval region or a square region and the like, and the shape of the hole region Hole may be set according to the actual requirements, which is not limited in the present application.

The winding display region A1 is configured to place winding lines, such as data signal lines, scanning signal lines, light-emitting control signal lines and the like.

It can be understand that the hole region Hole is a non-display region. The winding display region A1 is a display region.

As shown in FIGS. 1 and 2, the array substrate 100 includes a plurality of first pixel circuits PU1, a plurality of second pixel circuits PU2, a plurality of first signal lines 10, and a plurality of first connecting signal lines 20.

The plurality of first pixel circuit PU1 are distributed in an array in the winding display region A1. The plurality of second pixel circuit PU2 are distributed in an array in the main display region A2. As an example, the first pixel circuits PU1 and the second pixel circuits PU2 are configured to drive light-emitting elements emitting light.

An area of an orthographic projection of the first pixel circuit PU1 on a plane where the array substrate 100 is located is smaller than an area of an orthographic projection of the second pixel circuit PU2 on the plane where the array substrate 100 is located. That is, the area of the first pixel circuit PU1 is reduced relative to the second pixel circuit PU2. In order to improve the pixel density of the display panel, the density of the pixel circuits on the array substrate 100 is also relatively high. Usually, the pixel circuits on the entire array substrate are disposed immediately adjacent, that is, there is not enough space between two adjacent ones of the pixel circuits to place the signal line. As an example, the second pixel circuits PU2 are disposed immediately adjacent, and there is not enough space between two adjacent ones of the second pixel circuits PU2 to place the signal line. However, in the embodiment of the present application, since the area of the orthographic projection of the first pixel circuit PU1 on the plane where the array substrate 100 is located is smaller than the area of the orthographic projection of the second pixel circuit PU2 on the plane where the array substrate 100 is located, at least a part of the first pixel circuits PU1 are not disposed immediately adjacent, that is, the gap between two of the at least a part of the first pixel circuit PU1 is increased, and the increased gap can be configured to set the signal line.

Each of the first signal lines 10 is electrically connected to the first pixel circuit PU1 and the second pixel circuit PU2 and extends along a first direction X. It is understood that the plurality of first signal lines 10 are located in the display region AA. The plurality of first signal lines 10 include a plurality of first type signal lines 11 and a plurality of second type signal lines 12. Each of the first type signal lines 11 extends along the first direction X. Each of the second type signal lines 12 includes a first segment 121 and a second segment 122 separated by the hole region Hole and extending along the first direction X.

As an example, an orthographic projection of the first signal line 10 on the plane where the array substrate is located may overlap with the orthographic projections of the first pixel circuit PU1 and the second pixel circuit PU2 on the plane where the array substrate is located.

It is understood that the first type signal lines 11 are continuous lines, and the first type signal lines 11 are not separated by the hole region Hole.

In order to provide signals for the pixel driving circuit electrically connected to a same second type signal line 12, the first segment 121 and the second segment 121 separated by the hole region may be connected by using the first connecting signal line 20.

At least a part of the first connecting signal lines 20 are located in the winding display region A1. The first connecting signal line 20 includes a first connecting segment 21, a second connecting segment 22 and a third connecting segment 23 connected with each other. The second connecting segment 22 is connected between the first connecting segment 21 and the third connecting segment 23. The first connecting segment 21 is electrically connected to the first segment 121 (the black dot in figure indicates that the first connecting segment 21 is connected to the first segment 121), and the third connecting segment 23 is electrically connected to the second segment 122 (the black dot in figure indicates that the third connecting segment 23 is connected to the second segment 122). The first connecting segment 21 and the third connecting segment 23 extend in a second direction Y. The second connecting segment 22 extends in the first direction X. In order to clearly distinguish the first signal line 10 from the second connecting segment 22, the second connecting segment 22 is illustrated as a dotted line in the figure.

The orthographic projection of the first connecting signal line 20 on the plane where the array substrate 100 is located does not overlap with the orthographic projection of the first pixel circuit PU1 on the plane where the array substrate 100 is located. In the embodiment of the present application, by setting the area of the orthographic projection of the first pixel circuit PU1 on the plane where the array substrate 100 is located being smaller than the area of the orthographic projection of the second pixel circuit PU2 on the plane where the array substrate 100 is located, at least a part of the first pixel circuits PU1 are not disposed immediately adjacent, that is, the gap between two of the at least a part of the first pixel circuits PU1 is increased, so that the first connecting signal line 20 can be disposed in the increased gap.

In the embodiment of the present application, on the one hand, since at least a part of the first connecting signal lines 20 are disposed in the winding display region A1, the number of the first connecting signal lines 20 disposed in the border of the hole region Hole may be reduced, and the first connecting signal lines 20 may even not be disposed in the border of the hole region Hole. Therefore, the area of the border of the hole region Hole can be reduced, and the screen ratio of the array substrate can be increased. On the other hand, by reducing the area of the first pixel circuit PU1, the orthographic projection of the first connecting signal line 20 on the plane where the array substrate 100 is located does not overlap with the orthographic projection of the first pixel circuit PU1 on the plane where the array substrate 100 is located. Therefore, the possibility of forming parasitic capacitance between the first connecting signal line 20 and the first pixel circuit PU1 is reduced, the coupling effect between the first connecting signal line 20 and the first pixel circuit PU1 can be weakened, and the display effect is improved.

As an example, the first direction X intersects the second direction Y. The first direction X and the second direction Y may be perpendicular. For example, the first direction X may be a column direction, the second direction Y may be a row direction, and the first signal line 10 may be a data signal line. Further, the first direction X may be a row direction, the second direction Y may be a column direction, and the first signal line 10 may be a scanning signal line, a light-emitting control signal line or a reference voltage signal line, which is not limited in the present application.

In some alternative embodiments, a circuit structure of the first pixel circuit PU1 is the same as a circuit structure of the second pixel circuit PU2, and the first pixel circuit PU1 and the second pixel circuit PU2 each comprise at least one transistor, and wherein a size of the at least one transistor in the first pixel circuit PU1 is smaller than a size of the at least one transistor, at a same connecting position as the at least one transistor in the first pixel circuit PU1, in the second pixel circuit PU2.

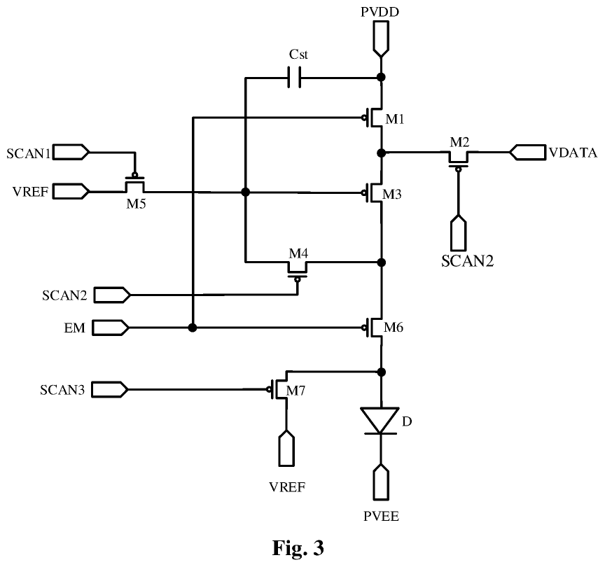

As an example, the circuit structures of the first pixel circuit PU1 and the second pixel circuit PU2 are both the circuit structure of 7T1C as shown in FIG. 3. Of course, the circuit structures of the first pixel circuit PU1 and the second pixel circuit PU2 may also be 2T1C, 4T1C, 6T1C, 6T2C, 7T2C and the like, which is not limited in the present application. Here, “T” represents a transistor, “C” represents a capacitor, and “7T1C” represents seven transistors and one capacitor, and so on.

As shown in FIG. 3, the first pixel circuit PU1 and the second pixel circuit PU2 each include a first light-emitting control transistor M1, a data writing transistor M2, a driving transistor M3, a compensation transistor M4, a first initialization transistor M5, a second light-emitting control transistor M6, a second initialization transistor M7, and a storage capacitor Cst. The connecting relationships of the elements are shown in FIG. 3 and will not be described here. In FIG. 3, PVDD and PVEE represent power supply signal lines. For example, the voltage on the PVDD signal line is greater than the voltage on the PVEE signal line. VDATA represents the data signal line, SCAN 1, SCAN 2 and SCAN 3 represent the scanning signal line, EM represents the light-emitting control signal line, and D represents the light-emitting element.

In order to make the area of the orthographic projection of the first pixel circuit PU1 on the plane where the array substrate 100 is located being smaller than the area of the orthographic projection of the second pixel circuit PU2 on the plane where the array substrate 100 is located, the size of any one transistor in the first pixel circuit PU1 may be set as being smaller than the size of the transistor at a same connecting position in the second pixel circuit PU2 as that transistor in the first pixel circuit PU1, and the sizes of the remaining transistors in the first pixel circuit PU1 may be equal to the sizes of the remaining transistors in the second pixel circuit PU2. For example, the size of the first light-emitting control transistor M1 in the first pixel circuit PU1 may be set as being smaller than the size of the first light-emitting control transistor M1 in the second pixel circuit PU2. Also, the sizes of a plurality of transistors in the first pixel circuit PU1 may be set as being smaller than the sizes of a plurality of transistors at same connecting positions in the second pixel circuit PU2 as the plurality of transistors in the first pixel circuit PU1, or the sizes of all transistors and the storage capacitor in the first pixel circuit PU1 may be set as being smaller than the sizes of all transistors and the storage capacitor at the same connecting positions in the second pixel circuit PU2 as all transistors and the storage capacitor in the first pixel circuit PU1. The present application does not limit the selection of the specific transistor in the first pixel circuit PU1, as long as the area of the orthographic projection of the first pixel circuit PU1 on the plane where the array substrate 100 is located is smaller than the area of the orthographic projection of the second pixel circuit PU2 on the plane where the array substrate 100 is located.

According to the embodiment of the present application, by setting the transistor in the first pixel circuit PU1 as a small size transistor, the first pixel circuit PU1 with a small orthographic projection area can be easily and conveniently realized, so that there is enough space between two adjacent ones of the first pixel circuits PU1 to set the signal line.

In other alternative embodiments, in order to make the area of the orthographic projection of the first pixel circuit PU1 on the plane where the array substrate 100 is located being smaller than the area of the orthographic projection of the second pixel circuit PU2 on the plane where the array substrate 100 is located, a line width of the first signal line 10 in the winding display region A1 may be set as being smaller than a line width of the first signal line 10 in the main display region A2, and a spacing between two adjacent ones of the first signal lines 10 in the winding display region A1 may be set as being smaller than a spacing between two adjacent ones of the first signal lines 10 in the main display region A2.

In the process of preparing the first pixel circuit PU1 and the second pixel circuit PU2, the first signal line 10 may be reused as a gate or a source/drain of a transistor in the first pixel circuit PU1 and the second pixel circuit PU2. For example, the circuit structures of the first pixel circuit PU1 and the second pixel circuit PU2 are 7T1C shown in FIG. 3, the first electrode of the data writing transistor M2 is electrically connected with the data signal line VDATA. For example, the first signal line 10 is the data signal line, the portion of the first signal line 10 connected to the semiconductor layer of the data writing transistor M2 is reused as the first electrode of the data writing transistor M2, and the first electrode of the data writing transistor M2 is a source/drain. For example, the first signal line 10 is the scanning signal line SCAN 1, and the portion of the first signal line 10 overlapping with the semiconductor layer of the first initialization transistor M5 is reused as a gate of the first initialization transistor M5. For example, the first signal line 10 is a light-emitting control signal line EM, and the portion of the first signal line 10 overlapping with the semiconductor layers of the first light-emitting control transistor M1 and the second light-emitting control transistor M6 is reused as the gates of the first light-emitting control transistor M1 and the second light-emitting control transistor M6. Therefore, the line width of the first signal line 10 and the spacing between two adjacent ones of the first signal lines 10 in the winding display region A1 are reduced, which is equivalent to reducing the sizes of the transistors in the first pixel circuit PU1.

In the embodiment of the present application, by reducing the line width of the first signal line 10 and the spacing between two adjacent ones of the first signal lines 10 in the winding display region A1, the sizes of the transistors in the first pixel circuit PU1 can be easily and conveniently reduced, so that there is enough space between two adjacent ones of the first pixel circuits PU1 to set the signal line.

In some alternative embodiments, as shown in FIG. 2, the hole region Hole has a center line L in the second direction Y, the smaller a vertical distance in the second direction Y between the second type signal line 12 and the center line L, the smaller a vertical distance in the second direction Y between the center line L and the second connecting segment 22 electrically connected to the second type signal line 12, and the smaller the vertical distance in the second direction Y between the second type signal line 12 and the center line L, the smaller two vertical distances in the second direction Y respectively between the center line L and the first connecting segment 21 electrically connected to the second type signal line 12 and between the center line L and the third connecting segment 23 electrically connected to the second type signal line 12.

Taking the second type signal lines 12 on the innermost side and the outermost side of the plurality of second type signal lines 12 opposite to the hole region Hole as an example, the vertical distance in the second direction Y between the center line L and the second type signal line 12 on the innermost side of the plurality of second type signal lines 12 opposite to the hole region Hole is smallest, and the vertical distance in the second direction Y between the center line L and the second type signal line 12 on the outermost side of the plurality of second type signal lines 12 opposite to the hole region Hole is largest.

The second connecting segment 22 corresponding to the second type signal line 12 on the innermost side is disposed on the innermost side, and the first connecting segment 21 and the third connecting segment 23 corresponding to the second type signal lines 12 on the innermost side are disposed on the outermost side. The second connecting segment 22 corresponding to the second type signal line 12 on the outermost side is disposed on the outermost side, and the first connecting segment 21 and the third connecting segment 23 corresponding to the second type signal line 12 on the outermost side are disposed on the innermost side.

It is understood that the lengths of the first connecting segment 21 and the third connecting segment 23 of a same first connecting signal line 20 are equal.

According to the above arrangement, the length of the second connecting segment 22 corresponding to the second type signal line 12 on the innermost side is greater than the length of the second connecting segment 22 corresponding to the second type signal line 12 on the outermost side, and the lengths of the first connecting segment 21 and the third connecting segment 23 corresponding to the second type signal line 12 on the innermost side are less than the lengths of the first connecting segment 21 and the third connecting segment 23 corresponding to the second type signal line 12 on the outermost side. Therefore, the total length of the first connecting signal line 20 corresponding to the second type signal line 12 on the innermost side is equal to the total length of the first connecting signal line 20 corresponding to the second type signal line 12 on the outermost side, and the resistances of the first connecting signal lines 20 are equal. That is, the pressure drops of the first connecting signal lines 20 are equal, thereby facilitating uniformity of display.

In some alternative embodiments, the first connecting signal lines 20 may be evenly distributed within the winding display region A1. For example, in the second direction Y, the spacing between the second connecting segments 22 is the same. In the first direction X, the spacing between the first connecting segments 21 is the same, and the spacing between the third connecting segments 23 is the same.

In some alternative embodiments, a plurality of second connecting segments 22 may be evenly distributed on two sides of the hole region Hole in the second direction Y.

As an example, as shown in FIG. 2, the first pixel circuits PU1 arranged along the second direction Y in an interval between every two adjacent ones of the second connecting segments 22 on a same side of the hole region Hole have the same number, so that the spacing between every two adjacent ones of the second connecting segments 22 in the second direction Y is the same. The first pixel circuits PU1 arranged along the first direction X in an interval between every two adjacent ones of the first connecting segments 21 have the same number, so that the spacing between every two adjacent ones of the first connecting segments 21 in the first direction X is the same. The first pixel circuits PU1 arranged along the first direction X in an interval between every two adjacent ones of the third connecting segments 23 have the same number, so that the spacing between every two adjacent ones of the third connecting segments 23 in the first direction X is the same. Further, the number of the first pixel circuits PU1 arranged along the first direction X in an interval between two adjacent ones of the first connecting segments 21 is equal to the number of the first pixel circuits PU1 arranged along the first direction X in an interval between two adjacent ones of the third connecting segments 23, so that the spacing between the first connecting segments 21 in the first direction X is the same as the spacing between the third connecting segments 23 in the first direction X.

Further, on a same side of the hole region Hole, the number of the first pixel circuits PU1 arranged along the second direction Y in the interval between two adjacent ones of the second connecting segments 22 is equal to twice the number of the first pixel circuits PU1 arranged along the first direction X in the interval between two adjacent ones of the first connecting segments 21. Because that the number of the first pixel circuits PU1 arranged along the first direction X in the interval between two adjacent ones of the first connecting segments 21 is equal to the number of the first pixel circuits PU1 arranged along the first direction X in the interval between two adjacent ones of the third connecting segments 23, on a same side of the hole region Hole, the number of the first pixel circuits PU1 arranged along the second direction Y in the interval between two adjacent ones of the second connecting segments 22 is equal to twice the number of the first pixel circuits PU1 arranged along the first direction X in the interval between two adjacent ones of the third connecting segments 23.

For example, as shown in FIG. 2, on a same side of the hole region Hole, the number of the first pixel circuits PU1 arranged along the second direction Y in the interval between two adjacent ones of the second connecting segments 22 is two, the number of the first pixel circuits PU1 arranged along the first direction X in the interval between two adjacent ones of the first connecting segments 21 is one, and the number of the first pixel circuits PU1 arranged along the first direction X in the interval between two adjacent ones of the third connecting segments 23 is one. Taking the two first connecting signal lines 20 corresponding to two adjacent ones of the second type signal lines 12 on a same side of the center line L of the hole region Hole as an example, the length of the second connecting segment 22 closer to the center line L is longer than the length of the second connecting segment 22 farther from the center line L by approximately the length of two first pixel circuits PU1. Further, the length of the first connecting segment 21 closer to the center line L is shorter than the length of the first connecting segment 21 farther from the center line L by approximately the length of one first pixel circuit PU1, and the length of the third connecting segment 23 closer to the center line L is shorter than the length of the third connecting segment 23 farther from the center line L by approximately the length of one first pixel circuit PU1. Therefore, it is further ensured that the total lengths of the two first connecting signal lines 20 corresponding to the two adjacent ones of the second type signal lines 12 on the same side of the center line L of the hole region Hole are equal.

It is only an example that the number of the first pixel circuits PU1 arranged along the second direction Y in the interval between two adjacent ones of the second connecting segments 22 on the same side of the hole region Hole is two, and the number of the first pixel circuits PU1 arranged along the second direction Y in the interval between two adjacent ones of the second connecting segments 22 on the same side of the hole region Hole may be four, six, eight and so on, which is not limited in the present application. It is understood that the number of the first pixel circuits PU1 arranged along the second direction Y in the interval between two adjacent ones of the second connecting segments 22 on the same side of the hole region Hole is even.

In some alternative embodiments, the first pixel circuits PU1 arranged along the second direction Y in the interval between two adjacent ones of the second connecting segments 22 may be immediately adjacent to each other. Thus, under a condition that the size of the first pixel circuit PU1 is fixed, the gap between two adjacent ones of the first pixel circuits PU1 may be increased. Further, under a condition that the line width of the first connecting signal line 20 is fixed, the first connecting signal lines 20 can be guaranteed to be placed in the gap between two adjacent ones of the first pixel circuits PU1 without setting the size of the first pixel circuit PU1 too small.

In some alternative embodiments, the second connecting segment 22 and the first signal line 10 may be disposed in a same layer and of a same material, and the first connecting segment 21 may be located in a film layer different from the first signal line 10, and the third connecting segment 23 may be located in a film layer different from the first signal line 10. In this way, the second connecting segment 22 and the first signal line 10 can be formed in a same process step. Further, the extension directions of the first connecting segment 21 and the third connecting segment 23 intersect the extension direction of the first signal line 10. By setting the first connecting segment 21 being located in a film layer different from the first signal line 10 and setting the third connecting segment 23 being located in a film layer different from the first signal line 10, signal interference between the first connecting signal line 20 and the first signal line 10 can be avoided.

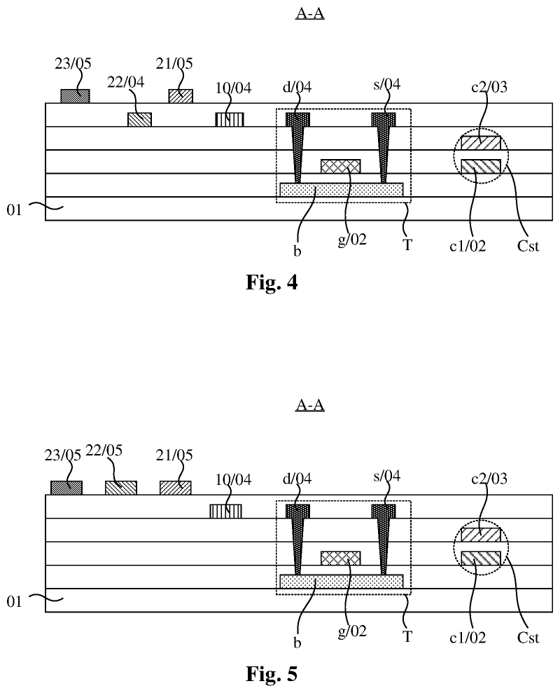

As an example, the first signal line 10 is the data signal line. As shown in FIG. 4, the array substrate 100 may include a substrate 01 as well as a first conductive layer 02, a second conductive layer 03, a third conductive layer 04, and a fourth conductive layer 05 stacked on a side of the substrate 01. An insulating layer is disposed between every two adjacent conductive layers. As an example, the first pixel circuit PU1 includes a transistor T and a storage capacitor Cst. The transistor T includes a semiconductor b, a gate g, a source s and a drain d. The storage capacitor Cst includes a first plate c1 and a second plate c2. As an example, the gate g and the first plate c1 may be located in the first conductive layer 02; the second plate c2 may be located in the second conductive layer 03; the source s, the drain d, the first signal line 10 and the second connecting segment 22 may be located in the third conductive layer 04; and the first connecting segment 21 and the third connecting segment 23 may be located in the fourth conductive layer 05. The first connecting segment 21 and the third connecting segment 23 may be connected with the second connecting segment 22 through vias.

In other alternative embodiments, the first connecting segment 21, the second connecting segment 22 and the third connecting segment 23 are located in a film layer different from the first signal line 10, and the first connecting segment 21, the second connecting segment 22 and the third connecting segment 23 are located in a same film layer. Thus, the first connecting segment 21, the second connecting segment 22 and the third connecting segment 23 can be formed simultaneously in a same process step, thereby avoiding signal interference between the first connecting signal line 20 and the first signal line 10.

As an example, the first signal line 10 is the data signal line. As shown in FIG. 5, the first signal line 10 may be located in the third conductive layer 04, and the first connecting segment 21, the second connecting segment 22, and the third connecting segment 23 may be located in the fourth conductive layer 05. The first connecting segment 21 and the third connecting segment 23 may be connected with the first signal line 10 through vias.

In some alternative embodiments, as shown in FIGS. 1 and 2, the first direction X may be a column direction, the second direction Y may be a row direction, and the first signal line 10 may be a data signal line.

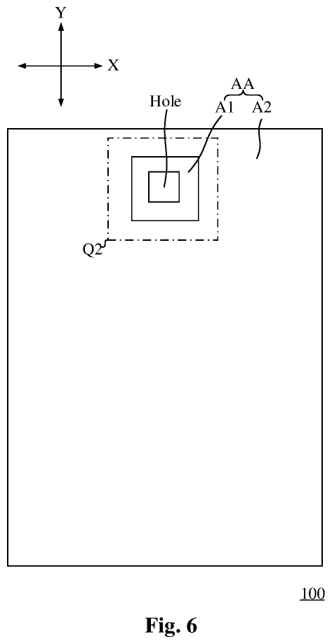

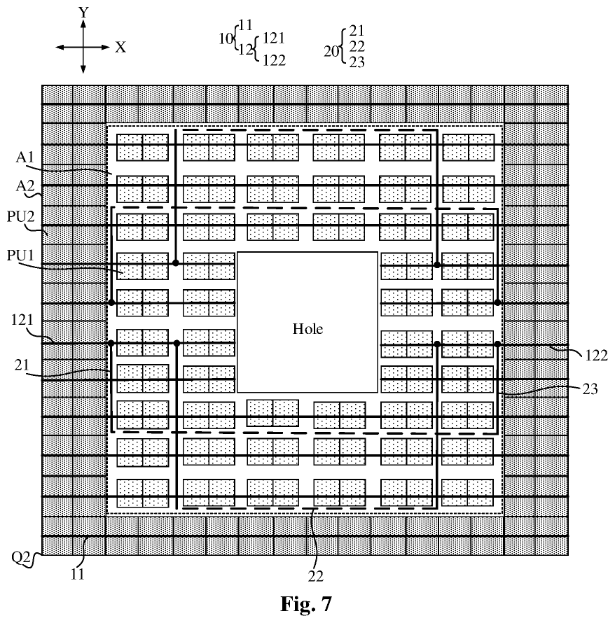

In other alternative embodiments, as shown in FIGS. 6 and 7, the first direction X may be a row direction, the second direction Y may be a column direction, and the first signal line 10 may be a scanning signal line, a light-emitting control signal line or a reference voltage signal line.

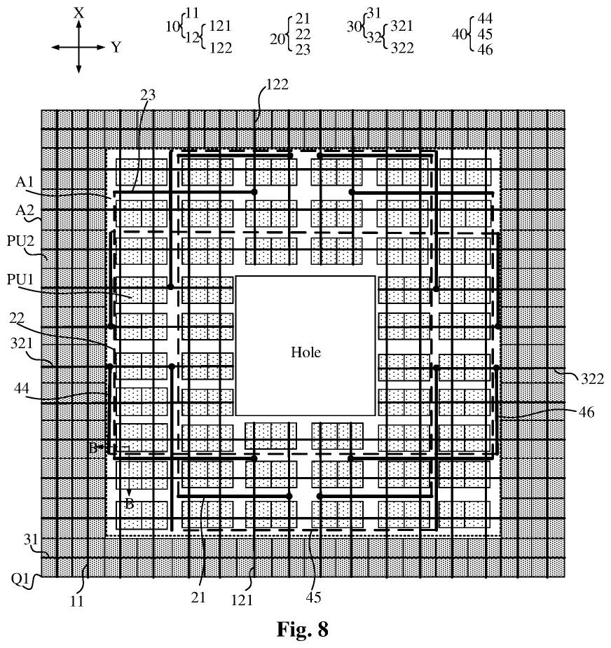

In some alternative embodiments, as shown in FIGS. 1 and 8, the first direction X is a column direction, the second direction Y is a row direction, the first signal line 10 is a data signal line, and the array substrate 100 further includes a plurality of second signal lines 30 and a plurality of second connecting signal lines 40.

The second signal line 30 is a scanning signal line, a light-emitting control signal line or a reference voltage signal line. Each of the second signal lines 30 is electrically connected to the first pixel circuit PU1 and the second pixel circuit PU2 and extends along the second direction Y. It is understood that the second signal lines 30 are located in the display region AA. The plurality of second signal lines 30 include a plurality of third type signal lines 31 and a plurality of fourth type signal lines 32, and each of the fourth type signal lines 32 includes a third segment 321 and a fourth segment 322 separated by the hole region Hole.

As an example, an orthographic projection of the second signal line 30 on the plane where the array substrate is located may overlap with the orthographic projections of the first pixel circuit and the second pixel circuit on the plane where the array substrate is located.

It is understood that the third type signal lines 31 are continuous lines, and the third type signal lines 31 are not separated by the hole region Hole.

In order to provide signals for the pixel driving circuit electrically connected to a same fourth type signal line 32, the third segment 321 and the fourth segment 322 separated by the hole region may be connected by using the second connecting signal line 40.

At least a part of the second connecting signal lines 40 are located in the winding display region A1. The second connecting signal line 40 includes a fourth connecting segment 44, a fifth connecting segment 45 and a sixth connecting segment 46 connected with each other. The fourth connecting segment 44 is electrically connected to the third segment 321 (the black dot in figure indicates that the fourth connecting segment 44 is connected to the third segment 321), and the sixth connecting segment 46 is electrically connected to the fourth segment 322 (the black dot in figure indicates that the sixth connecting segment 46 is connected to the fourth segment 322). The fifth connecting segment 45 is connected between the fourth connecting segment 44 and the sixth connecting segment 46. The fourth connecting segment 44 and the sixth connecting segment 46 extend in the first direction X. The fifth connecting segment 45 extends in the second direction Y. In order to clearly distinguish the second signal line 20 from the fifth connecting segment 45, the fifth connecting segment 45 is illustrated as a dotted line in the figure.

The orthographic projection of the second connecting signal line 40 on the plane where the array substrate is located does not overlap with the orthographic projection of the first pixel circuit PU1 on the plane where the array substrate 100 is located. In the embodiment of the present application, by setting the area of the orthographic projection of the first pixel circuit PU1 on the plane where the array substrate 100 is located being smaller than the area of the orthographic projection of the second pixel circuit PU2 on the plane where the array substrate 100 is located, at least a part of the first pixel circuits PU1 are not disposed immediately adjacent, that is, the gap between two of the at least a part of the first pixel circuit PU1 is increased, so that the first connecting signal line 20 and the second connecting signal line 40 can be disposed in the increased gap.

In the embodiment of the present application, by reducing the area of the first pixel circuit PU1, the orthographic projections of the first connecting signal line 20 and the second connecting signal line 40 on the plane where the array substrate 100 is located does not overlap with the orthographic projection of the first pixel circuit PU1 on the plane where the array substrate 100 is located. Therefore, the possibility of forming parasitic capacitance between the first connecting signal line 20 and the first pixel circuit PU1 and between the second connecting signal line 40 and the first pixel circuit PU1 is reduced, the coupling effect between the first connecting signal line 20 and the first pixel circuit PU1 and between the second connecting signal line 40 and the first pixel circuit PU1 can be weakened, and the display effect is improved.

The second connecting signal lines 40 may be arranged according to the arrangement mode of the first connecting signal lines 20 in the above embodiment, which will not be described here.

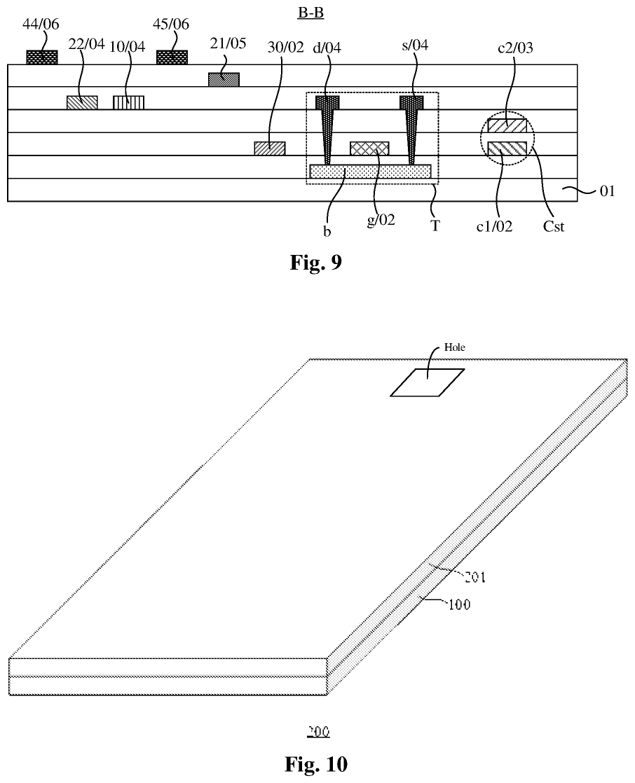

As an example, as shown in FIG. 9, the array substrate 100 may further include a fifth conductive layer 06. An insulating layer is disposed between every two adjacent conductive layers. The first signal line 10 and the second connecting segment 22 may be located in the third conductive layer 04; the first connecting segment 21 and the third connecting segment 23 (not shown in FIG. 9) may be located in the fourth conductive layer 05; the second signal line 30 may be located in the first conductive layer 02; and the fourth connecting segment 44, the fifth connecting segment 45 (not shown in FIG. 9) and the sixth connecting segment 46 may be located in the fifth conductive layer 06.

The embodiment of the present application further provides a display panel comprising the array substrate as described in any of the above embodiments. FIG. 10 illustrates a schematic structural diagram of a display panel provided by an embodiment of the present application. As shown in FIG. 10, the display panel 200 includes the array substrate 100 as described in any of the above embodiments and a light-emitting layer 201 located on the array substrate 100. As an example, the light-emitting layer 201 may be an organic light-emitting layer, that is, the display panel 200 may be an organic light-emitting diode (OLED) display panel.

The principle of the display panel is similar to that of the aforementioned array substrate, so that the implementation of the display panel can be referred to the implementation of the aforementioned array substrate, which will not be repeated here.

The embodiment of the present application further provides a display device comprising the display panel 200 as described in the above embodiment. The display device may be any electronic device with a display function, such as a mobile phone, a tablet computer, a laptop computer, an electronic paper book, or a television set.

According to the embodiments of the present application as described above, these embodiments do not describe all the details and do not limit the present application to the specific embodiments as described. Obviously, there are many modifications and changes that can be made based on the above description. This specification selects and describes these embodiments in order to better explain the principle and practical application of the present application, so that those skilled in the art can make good use of the present application and the modification of the present application. The present application is limited only by the claim and its full scope and equivalents.

1-20. (canceled)

21. An array substrate comprising a hole region and a display region, wherein the display region comprises a winding display region and a main display region, the winding display region is located between the hole region and the main display region, and the winding display region surrounds the hole region;
wherein the array substrate comprises:
a plurality of first pixel circuits distributed in an array in the winding display region;
a plurality of second pixel circuits distributed in an array in the main display region;
a plurality of first signal lines, wherein each of the first signal lines is electrically connected to the first pixel circuit and the second pixel circuit and extends along a first direction, the plurality of first signal lines comprise a plurality of first type signal lines and a plurality of second type signal lines, and each of the second type signal lines comprises a first segment and a second segment separated by the hole region;
a plurality of first connecting signal lines, wherein at least a part of the first connecting signal lines are located in the winding display region, the first connecting signal line comprises a first connecting segment, a second connecting segment and a third connecting segment connected with each other, the first connecting segment is electrically connected to the first segment, the third connecting segment is electrically connected to the second segment, and the second connecting segment is connected between the first connecting segment and the third connecting segment, wherein the first connecting segment and the third connecting segment extend in a second direction, and the second connecting segment extends in the first direction;
wherein an area of an orthographic projection of the first pixel circuit on a plane where the array substrate is located is smaller than an area of an orthographic projection of the second pixel circuit on the plane where the array substrate is located, and an orthographic projection of the first connecting signal line on the plane where the array substrate is located does not overlap with the orthographic projection of the first pixel circuit on the plane where the array substrate is located.

22. The array substrate according to claim 21, wherein a circuit structure of the first pixel circuit is the same as a circuit structure of the second pixel circuit, and the first pixel circuit and the second pixel circuit each comprise at least one transistor, and wherein a size of the at least one transistor in the first pixel circuit is smaller than a size of the at least one transistor, at a same connecting position as the at least one transistor in the first pixel circuit, in the second pixel circuit.

23. The array substrate according to claim 22, wherein a line width of the first signal line in the winding display region is smaller than a line width of the first signal line in the main display region, and a spacing between two adjacent ones of the first signal lines in the winding display region is smaller than a spacing between two adjacent ones of the first signal lines in the main display region.

24. The array substrate according to claim 21, wherein the hole region has a center line in the second direction, the smaller a vertical distance in the second direction between the second type signal line and the center line, the smaller a vertical distance in the second direction between the center line and the second connecting segment electrically connected to the second type signal line; and the smaller the vertical distance in the second direction between the second type signal line and the center line, the smaller two vertical distances in the second direction respectively between the center line and the first connecting segment electrically connected to the second type signal line and between the center line and the third connecting segment electrically connected to the second type signal line.

25. The array substrate according to claim 24, wherein the first pixel circuits arranged along the second direction in an interval between every two adjacent ones of the second connecting segments on a same side of the hole region have the same number, and the number of the first pixel circuits arranged along the first direction in an interval between two adjacent ones of the first connecting segments is equal to the number of the first pixel circuits arranged along the first direction in an interval between two adjacent ones of the third connecting segments;
wherein on a same side of the hole region, the number of the first pixel circuits arranged along the second direction in the interval between two adjacent ones of the second connecting segments is equal to twice the number of the first pixel circuits arranged along the first direction in the interval between two adjacent ones of the first connecting segments.

26. The array substrate according to claim 25, wherein the first pixel circuits arranged along the second direction in the interval between two adjacent ones of the second connecting segments are adjacent to each other.

27. The array substrate according to claim 21, wherein the second connecting segment and the first signal line are disposed in a same layer and of a same material, and the first connecting segment is located in a film layer different from the first signal line, and the third connecting segment is located in a film layer different from the first signal line.

28. The array substrate according to claim 21, wherein the first connecting segment, the second connecting segment and the third connecting segment are located in a film layer different from the first signal line, and the first connecting segment, the second connecting segment and the third connecting segment are located in a same film layer.

29. The array substrate according to claim 21, wherein the first direction is a column direction, the second direction is a row direction, and the first signal line is a data signal line.

30. The array substrate according to claim 21, wherein the first direction is a row direction, the second direction is a column direction, and the first signal line is a scanning signal line, a light-emitting control signal line or a reference voltage signal line.

31. The array substrate according to claim 21, wherein the first direction is a column direction, the second direction is a row direction, the first signal line is a data signal line, and the array substrate further comprises:
a plurality of second signal lines, wherein each of the second signal lines is electrically connected to the first pixel circuit and the second pixel circuit and extends along the second direction, the plurality of second signal lines comprise a plurality of third type signal lines and a plurality of fourth type signal lines, and each of the fourth type signal lines comprises a third segment and a fourth segment separated by the hole region;
a plurality of second connecting signal lines, wherein at least a part of the second connecting signal lines are located in the winding display region, the second connecting signal line comprises a fourth connecting segment, a fifth connecting segment and a sixth connecting segment connected with each other, the fourth connecting segment is electrically connected to the third segment, the sixth connecting segment is electrically connected to the fourth segment, and the fifth connecting segment is connected between the fourth connecting segment and the sixth connecting segment, wherein the fourth connecting segment and the sixth connecting segment extend in the first direction, and the fifth connecting segment extends in the second direction;
wherein an orthographic projection of the second connecting signal line on the plane where the array substrate is located does not overlap with the orthographic projection of the first pixel circuit on the plane where the array substrate is located.

32. The array substrate according to claim 31, wherein the second signal line is a scanning signal line, a light-emitting control signal line or a reference voltage signal line.

33. The array substrate according to claim 31, wherein the first direction is a column direction, the second direction is a row direction, and the first signal line is a data signal line.

34. A display panel comprising the array substrate according to claim 21.

35. A display device comprising the display panel according to claim 34.
